(19) United States
(12) Patent Application Publication
(10) Pub. No.: US 2025/0299614 A1
(43) Pub. Date: Sep. 25, 2025

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Wei WANG, Wuhan, Hubei (CN); Qing HUANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/861,604

(22) PCT Filed: Jun. 30, 2023
(86) PCT No.: PCT/CN2023/104452

§ 371 Date: Oct. 30, 2024

(30) Foreign Application Priority Data
Oct. 25, 2022 (CN) 202211313137.3

(51) Int. Cl. G09G 3/20

(52) U.S. Cl. CPC G09G 3/2092; G09G 2300/043; G09G 2310/0254; G09G 2310/0267; G09G 2310/08; G09G 2320/0233

(57) ABSTRACT

A display panel and a display device are provided. The display panel includes a substrate; a shielding layer disposed on the substrate; and a driving circuit layer disposed on a side of the shielding layer away from the substrate. The driving circuit layer includes a driving function transistor in the scan driving circuit sub-area. The shielding layer includes a first shielding portion between the driving function transistor and the substrate, and the first shielding portion is configured to be supplied with a variable voltage.

### TECHNICAL FIELD

The present application relates to the field of display technologies, and more particularly, to a display panel and a display device having the same.

### BACKGROUND

Gate Driver On Array (or Gate On Array, referred briefly to as GOA) circuit technique is a technique that circuits for the row scan driving signals of the Gate lines are manufactured on an array substrate by using a conventional array process for the thin film transistor liquid crystal display (referred briefly to as TFT-LCD), so as to realize a driving manner of scanning the gate lines row by row. Compared with the conventional processes of Chip On Film (referred briefly to as COF) and Chip On Glass (referred briefly to as COG), the manufacturing cost is not only saved, but also the process of bonding gates is eliminated in the application, which is extremely advantageous for improving the productivity and improving the integration degree of the display device.

In the GOA circuit, the substrate below the thin film transistors easily generates charges under voltage induction, and thus a back gate effect occurs and acts on the thin film transistors, so that the threshold voltage of the thin film transistor drifts, which affects the stability of the thin film transistor and further affects the signal output of the GOA circuit, thereby affecting the display effect of the display device.

### SUMMARY

Embodiments of the present application provide a display panel and a display device, which may effectively improve the stability of the driving function transistors and improve the driving current of the driving function transistors in a scan driving circuit sub-area.

Embodiments of the present application provide a display panel including a display area, a non-display area adjacent to the display area, the non-display area including a scan driving circuit sub-area;
the display panel further including:
a substrate;
a shielding layer disposed on the substrate; and
a driving circuit layer disposed on a side of the shielding layer which is away from the substrate, wherein the driving circuit layer includes a driving function transistor disposed in the scan driving circuit sub-area;
in which the shielding layer includes a first shielding portion between the driving function transistor and the substrate, and the first shielding portion is configured to be supplied with a voltage that is variable.

In embodiments of the present application, the driving circuit layer further includes a display function transistor disposed in the display area, and the shielding layer further includes a second shielding portion disposed between the display function transistor and the substrate;
in which when both the driving function transistor and the display function transistor are turned on, a polarity of the voltage of the first shielding portion is opposite to a polarity of a voltage of the second shielding portion, and when both the driving function transistor and the display function transistor are turned off, the polarity of the voltage of the first shielding portion is the same as the polarity of the voltage of the second shielding portion.

In embodiments of the present application, a polarity of the voltage of the first shielding portion is a negative polarity when the driving function transistor is turned on, and a polarity of the voltage of the first shielding portion is a positive polarity when the driving function transistor is turned off.

In embodiments of the present application, the driving function transistor includes an active layer, a gate, a source, and a drain, wherein the active layer is provided on a side of the first shielding portion which is away from the substrate, the gate is provided on a side of the active layer which is away from the first shielding portion, the source and the drain are provided on a side of the gate which is away from the active layer, and the source and the drain overlap with two sides of the active layer;
in which the first shielding portion is electrically connected to the gate.

In embodiments of the present application, the display panel further includes a scan driving circuit disposed in the scan driving circuit sub-area, the scan driving circuit includes a plurality of scan driving units cascaded, and each of the plurality of scan driving units includes a first node control module, a second node control module, and an output module;
the first node control module is electrically connected to a first node and electrically connected to the second node control module, and the first node control module is configured to control a potential of the first node;
the second node control module is electrically connected to a second node and electrically connected to the first node control module, and the second node control module is configured to control a potential of the second node;
the output module is electrically connected to the first node, the second node, and a signal output terminal of a present stage, and the output module is configured to control a potential of the signal output terminal of the present stage under a control of the potential of the first node and the potential of the second node;
in which the driving function transistor is disposed at least in the output module.

In embodiments of the present application, the output module includes a first transistor connected between the signal output terminal of the present stage and the first node, and the driving function transistor includes the first transistor.

In embodiments of the present application, the first node control module is electrically connected to a signal output terminal of a previous stage, the first node control module further includes a second transistor and a third transistor connected between the signal output terminal of the previous stage and the first transistor, and the driving function transistor further includes a second transistor and/or a third transistor.

According to the above-mentioned purpose of the present application, the embodiments of the present application provide a display panel including a display area, a non-display area adjacent to the display area, and the non-display area including a scan driving circuit sub-area;

The display panel further including:
a substrate;
a shielding layer disposed on the substrate; and
a driving circuit layer disposed on a side of the shielding layer which is away from the substrate, wherein the driving circuit layer includes one or more driving function transistors disposed in the scan driving circuit sub-area and one or more display function transistors disposed in the display region;
in which the shielding layer includes one or more first shielding portions each of which is between a corresponding one of the one or more driving function transistors and the substrate, and one or more second shielding portions each of which is disposed between a corresponding one of the one or more display function transistors and the substrate, and the first shielding portion is connected to the second shielding portion.

In embodiments of the present application, the driving circuit layer includes a plurality of the driving function transistors disposed in the scan driving circuit sub-area, and a plurality of the display function transistors disposed in the display region; the shielding layer includes a plurality of the first shielding portions each of which is between a corresponding one of the driving function transistors and the substrate, and a plurality of the second shielding portions each of which is between a corresponding one of the display function transistors and the substrate;
in which the plurality of first shielding portions and the plurality of second shielding portions are connected to form a network structure.

In embodiments of the present application, the display panel further includes a scan driving circuit disposed in the scan driving circuit sub-area, the scan driving circuit includes a plurality of scan driving units cascaded, and each of the plurality of scan driving units includes a first node control module, a second node control module, and an output module;
the first node control module is electrically connected to a first node and electrically connected to the second node control module, and the first node control module is configured to control a potential of the first node;
the second node control module is electrically connected to a second node, and electrically connected to the first node control module, and the second node control module is configured to control a potential of the second node;
the output module is electrically connected to the first node, the second node, and a signal output terminal of a present stage, and the output module is configured to control a potential of the signal output terminal of the present stage under a control of the potential of the first node and the potential of the second node;
in which the one or more driving function transistors are disposed at least in the output module.

In embodiments of the present application, the output module includes a first transistor connected between the signal output terminal of the present stage and the first node, and the driving function transistor includes the first transistor.

In embodiments of the present application, the first node control module is electrically connected to a signal output terminal of a previous stage, the first node control module further includes a second transistor and a third transistor connected between the signal output terminal of the previous stage and the first transistor, and the driving function transistor further includes the second transistor and/or the third transistor.

In embodiments of the present application, the display panel further includes a plurality of pixel driving units provided in the display area, the one or more display function transistors are provided in the pixel driving units;
in which an area of an orthographic projection of the first shielding portion, which is corresponding to a respective one of the plurality of scan driving units, on the substrate is larger than an area of an orthographic projection of the second shielding portion, which is corresponding to a respective one of the pixel driving units, on the substrate.

According to the above-mentioned purpose of the present application, embodiments of the present application further provide a display device including a display panel including a display area, a non-display area adjacent to the display area, the non-display area including a scan driving circuit sub-area;
the display panel further including:
a substrate;
a shielding layer disposed on the substrate; and
a driving circuit layer disposed on a side of the shielding layer which is away from the substrate, wherein the driving circuit layer includes a driving function transistor disposed in the scan driving circuit sub-area;
in which the shielding layer includes a first shielding portion between the driving function transistor and the substrate, and the first shielding portion is configured to be supplied with a voltage that is variable.

In embodiments of the present application, the driving circuit layer further includes a display function transistor disposed in the display area, and the shielding layer further includes a second shielding portion disposed between the display function transistor and the substrate;
in which when both the driving function transistor and the display function transistor are turned on, a polarity of the voltage of the first shielding portion is opposite to a polarity of a voltage of the second shielding portion, and when both the driving function transistor and the display function transistor are turned off, the polarity of the voltage of the first shielding portion is the same as the polarity of the voltage of the second shielding portion.

In embodiments of the present application, a polarity of the voltage of the first shielding portion is a negative polarity when the driving function transistor is turned on, and a polarity of a voltage of the first shielding portion is a positive polarity when the driving function transistor is turned off.

In embodiments of the present application, the driving function transistor includes an active layer, a gate, a source, and a drain, wherein the active layer is provided on a side of the first shielding portion which is away from the substrate, the gate is provided on a side of the active layer which is away from the first shielding portion, the source and the drain are provided on a side of the gate which is away from the active layer, and the source and the drain overlap with two sides of the active layer;
in which the first shielding portion is electrically connected to the gate.

In embodiments of the present application, the display panel further includes a scan driving circuit disposed in the scan driving circuit sub-area, the scan driving circuit includes a plurality of scan driving units cascaded, and each of the scan driving units includes a first node control module, a second node control module, and an output module;
the first node control module is electrically connected to a first node and electrically connected to the second node control module, and the first node control module is configured to control a potential of the first node;
the second node control module is electrically connected to a second node and electrically connected to the first node control module, and the second node control module is configured to control a potential of the second node;
the output module is electrically connected to the first node, the second node, and a signal output terminal of a present stage, and the output module is configured to control a potential of the signal output terminal of the present stage under a control of the potential of the first node and the potential of the second node;
in which the driving function transistor is disposed at least in the output module.

In embodiments of the present application, the output module includes a first transistor connected between the signal output terminal of the present stage and the first node, and the driving function transistor includes the first transistor.

In embodiments of the present application, the first node control module is electrically connected to a signal output terminal of a previous stage, the first node control module further includes a second transistor and a third transistor connected between the signal output terminal of the previous stage and the first transistor, and the driving function transistor further includes the second transistor and/or the third transistor.

### BENEFICIAL EFFECT

In the present application, a first shielding portion is provided between a driving function transistor in a scan driving circuit sub-area and a substrate, and the first shielding portion has an electric field shielding effect, so that charges generated by voltage induction in the substrate do not affect a threshold voltage of the driving function transistor, thereby improving stability of the driving function transistor, further improving stability of an output voltage in the scan driving circuit sub-area, and improving brightness stability and display effect of the display panel. In addition, the variable voltage is applied to the first shielding portion. Since the first shielding portion is located below the driving function transistor, the polarity of the voltage applied to the first shielding portion can be adjusted to increase the driving current of the driving function transistor, thereby further improving the signal transmission efficiency and the display effect of the display panel.

### BRIEF DESCRIPTION OF THE DRAWINGS

The technical solution and other beneficial effects of the present application will be apparent from the following detailed description of specific embodiments thereof, taken in conjunction with the accompanying drawings.

FIG. 1 is a schematic structural diagram of a display panel according to an embodiment of the present application;

FIG. 2 is another schematic structural diagram of a display panel according to an embodiment of the present application;

FIG. 3 is yet another schematic structural diagram of a display panel according to an embodiment of the present application;

FIG. 4 is yet another schematic structural diagram of a display panel according to an embodiment of the present application;

FIG. 5 is a schematic structural diagram of a scan driving unit according to an embodiment of the present application;

FIG. 6 is a timing diagram of a scan driving unit according to an embodiment of the present application;

FIG. 7 is a graph showing a relationship between a lighting timing and brightness of a display panel according to an embodiment of the present application;

FIG. 8 is a graph showing a relationship between a threshold voltage of a transistor and brightness according to an embodiment of the present application;

FIG. 9 is a graph showing a relationship between a threshold voltage of a transistor and source-drain current according to an embodiment of the present application;

FIG. 10 is a diagram showing a waveform output by a scan driving unit according to an embodiment of the present application; and

FIG. 11 is a graph showing a relationship between a voltage output by a scan driving circuit and brightness according to an embodiment of the present application.

### DETAILED DESCRIPTION

The technical solution in the embodiments of the present application will be clearly and completely described with reference to the accompanying drawings. It will be apparent that the described embodiments are only a part of the examples of the present application, and not all examples. Based on the embodiments in the present application, all other embodiments obtained by a person skilled in the art without involving any inventive effort are within the scope of the present application.

The following disclosure provides many different embodiments or examples for implementing the different structures of the present application. In order to simplify the disclosure of the present application, components and arrangements of specific examples are described below. Of course, they are merely examples and are not intended to limit the application. In addition, the present application may repeat reference numerals and/or reference letters in various examples, and such repetition is for the purpose of simplicity and clarity, without repetition itself indicating relationships between the embodiments and/or arrangements discussed. In addition, the present application provides examples of various specific processes and materials, but one of ordinary skill in the art will recognize the application of other processes and/or the use of other materials.

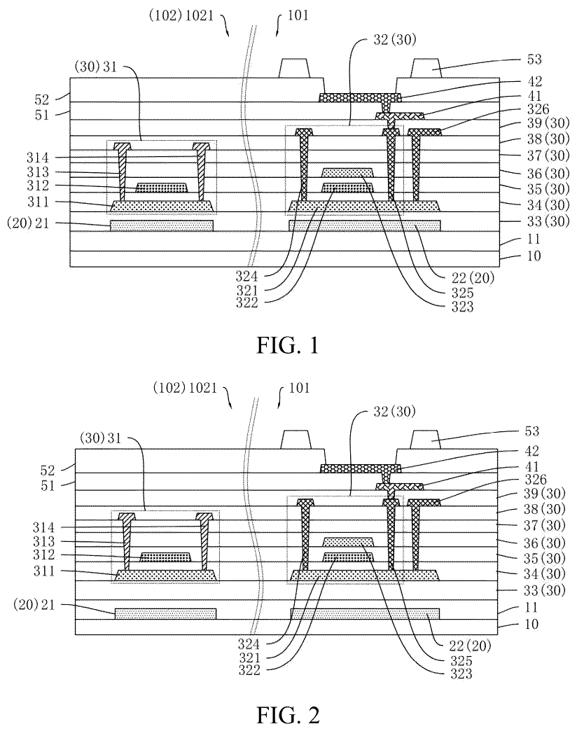

An embodiment of the present application provides a display panel. Referring to FIG. 1, the display panel includes a display area 101, a non-display area 102 adjacent to the display area 101. The non-display area 102 includes a scan driving circuit sub-area 1021.

Further, the display panel further includes a substrate 10, a shielding layer 20, and a driving circuit layer 30. The shielding layer 20 is disposed on the substrate 10. The driving circuit layer 30 is disposed on a side of the shielding layer 20 remote from the substrate 10. The driving circuit layer 30 includes driving function transistor(s) 31 disposed in the scan driving circuit sub-area 1021.

The shielding layer 20 includes a first shielding portion 21 between the driving function transistor 31 and the substrate 10. The first shielding portion 21 is supplied with a variable voltage.

In the actual application, the first shielding portion 21 is provided between the substrate 10 and the driving function transistor 31 located in the scan driving circuit sub-area 1021, and the first shielding portion 21 has an electric field shielding effect, so that the charges generated by voltage induction in the substrate 10 do not affect the threshold voltage of the driving function transistor 31, thereby improving the stability of the driving function transistor 31, and further improving the stability of the output voltage of the scan driving circuit sub-area 1021, and improving the brightness stability and the display effect of the display panel. In addition, in the embodiments of the present application, a variable voltage is applied to the first shielding portion 21. Since the first shielding portion 21 is located below the driving function transistor 31, the polarity of the voltage applied to the first shielding portion 21 may be adjusted to increase the driving current of the driving function transistor 31, thereby further improving the signal transmission efficiency and the display effect of the display panel.

Specifically, with continued reference to FIG. 1, an embodiment of the present application provides a display panel including a substrate 10, a passivation layer 11 disposed on the substrate 10, a shielding layer 20 disposed on the passivation layer 11, a driving circuit layer 30 disposed on the shielding layer 20, a planarization layer 51 disposed on the driving circuit layer 30, a pixel definition layer 52 disposed on the planarization layer 51, and spacer posts 53 disposed on the pixel definition layer 52.

The substrate 10 may be a flexible substrate, and the substrate 10 includes at least one polyimide layer.

The driving circuit layer 30 includes a plurality of thin film transistors and an insulating layer covering the plurality of thin film transistors. The plurality of thin film transistors include display function transistor(s) 32 disposed in the display region 101 and driving function transistor(s) 31 disposed in the scan driving circuit sub-area 1021. The insulating layer includes a buffer layer 33 disposed on the passivation layer 11, a first insulating layer 34 disposed on the buffer layer 33, a first gate insulating layer 35 disposed on the first insulating layer 34, a second gate insulating layer 36 disposed on the first gate insulating layer 35, a second insulating layer 37 disposed on the second gate insulating layer 36, a third insulating layer 38 disposed on the second insulating layer 37, and an interlayer dielectric layer 39 disposed on the third insulating layer 38.

The shielding layer 20 includes a first shielding portion 21 disposed between the driving function transistor 31 and the substrate 10, and a second shielding portion 22 disposed between the display function transistor 32 and the substrate 10. So, the charges generated by voltage induction in the substrate 10 do not affect the threshold voltage of the driving function transistor 31, thereby improving the stability of the driving function transistor 31, and further improving the stability of the output voltage of the scan driving circuit sub-area 1021.

A display active layer 321 of the display function transistor 32 is disposed on the buffer layer 33 and covered by the first insulating layer 34. A first display gate 322 of the display function transistor 32 is disposed on the first insulating layer 34 and covered by the first gate insulating layer 35. A second display gate 323 of the display function transistor 32 is disposed on the first gate insulating layer 35 and covered by the second gate insulating layer 36. A display source 324 and a display drain 325 of the display function transistor 32 are disposed on the third insulating layer 38 and covered by the interlayer dielectric layer 39. The display active layer 321 is disposed on a side of the second shielding portion 22 remote from the substrate 10. The display source 324 and the display drain 325 are overlapped with two sides of the display active layer 321 by passing through the third insulating layer 38, the second insulating layer 37, the second gate insulating layer 36, the first gate insulating layer 35, and the first insulating layer 34, respectively. The first display gate 322 is disposed on a side of the display active layer 321 remote from the substrate 10. The second display gate 323 is disposed on a side of the first display gate 322 remote from the display active layer 321. Further, the driving circuit layer 30 further includes a functional signal line 326 disposed on the third insulating layer 38 and covered by the interlayer dielectric layer 39. The functional signal line 326 overlaps a side of the display active layer 321 by passing through the third insulating layer 38, the second insulating layer 37, the second gate insulating layer 36, the first gate insulating layer 35, and the first insulating layer 34, that is, is electrically connected to the display drain 325.

In addition, the display panel further includes an interconnection portion 41 disposed on the interlayer dielectric layer 39 and covered by the planarization layer 51, and an anode 42 disposed between the planarization layer 51 and the pixel definition layer 52. The interconnection portion 41 overlaps the display drain 325 by passing through the interlayer dielectric layer 39. The anode 42 overlaps the interconnection portion 41 by passing through the planarization layer 51. So, the anode 42 is electrically connected to the display drain 325 for transmission of electrical signals.

Further, the driving function transistor 31 includes an active layer 311, a gate 312, a source 313, and a drain 314. The active layer 311 is disposed on the buffer layer 33 and covered by the first insulating layer 34. The gate 312 is disposed on the first insulating layer 34 and covered by the first gate insulating layer 35. The source 313 and the drain 314 are disposed on the second insulating layer 37 and covered by the third insulating layer 38. The active layer 311 is disposed on a side of the first shielding portion 21 away from the substrate 10. The gate 312 is disposed on a side of the active layer 311 away from the first shielding portion 21. The source 313 and the drain 314 are disposed on a side of the gate 312 away from the active layer 311. The source 313 and the drain 314 overlap two sides of the active layer 311 by passing through the second insulating layer 37, the second gate insulating layer 36, the first gate insulating layer 35, and the first insulating layer 34, respectively.

In the embodiment of the present application, by providing the first shielding portion 21 between the driving function transistor 31 and the substrate 10, the charge interference generated in the substrate 10 may be shielded, so that the stability of the driving function transistor 31 is improved, the output stability of the scan driving circuit is improved, and the display effect of the display panel is further improved.

It will be appreciated that the first shielding portion 21 and the second shielding portion 22 may be provided in the same layer, or may be provided in different layers. The arrangements of both the first shielding portion 21 and the second shielding portion 22 may be selected according to actual requirements, and details are not described herein.

In one embodiment of the present application, the shielding layer 20 may be provided on the substrate 10 and covered by the passivation layer 11. That is, both the first shielding portion 21 and the second shielding portion 22 are provided on the substrate 10 and covered by the passivation layer 11, as shown in FIG. 2.

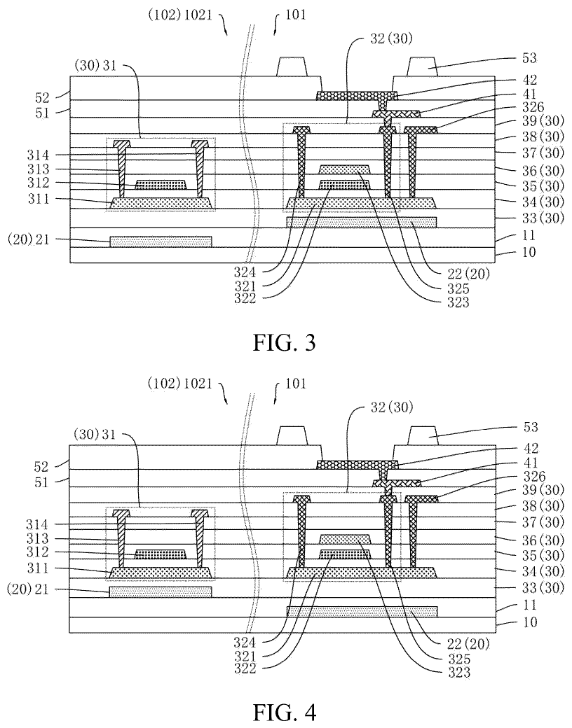

In another embodiment of the present application, the shielding layer 20 includes a first shielding sublayer and a second shielding sublayer. The first shielding sublayer is disposed on the substrate 10 and covered by the passivation layer 11. The second shielding sublayer is disposed on the passivation layer 11 and covered by the buffer layer 33. The first shielding portion 21 may be disposed on the first shielding sublayer, that is on the substrate 10 and covered by the passivation layer 11; the second shielding portion 22 may be disposed on the second shielding sublayer, that is on the passivation layer 11 and covered by the buffer layer 33, as shown in FIG. 3. Alternatively, the first shielding portion 21 may be located on the second shielding sublayer, i.e., on the passivation layer 11 and covered by the buffer layer 33; and the second shielding portion 22 may be located on the first shielding sublayer, i.e., on the substrate 10 and covered by the passivation layer 11, as shown in FIG. 4.

It should be noted that the display panel further includes a scan driving circuit provided in the scan driving circuit sub-area 1021. In the embodiment of the present application, the first shielding portion 21 may be loaded with a variable voltage, and the polarity of the voltage of the first shielding portion 21 may be adjusted during the driving of the driving function transistor 31 so as to increase the driving current of the driving function transistor 31, thereby improving the strength and the efficiency of the signal output by the scan driving circuit and further improving the display effect of the display panel.

In the embodiment of the present application, the first shielding portion 21 may be electrically connected to the gate 312 so that the potential of the first shielding portion 21 varies along with the change of the potential of the gate 312, so as to shield the charge interference and increase the driving current of the driving function transistor 31.

Specifically, when the driving function transistors 31 and the display function transistors 32 are turned on, the polarities of the voltages applied to the first shielding portions 21 are opposite to the polarities of the voltages applied to the second shielding portions 22. When the driving function transistors 31 and the display function transistors 32 are turned off, the polarities of the voltages applied to the first shielding portions 21 are the same as the polarities of the voltages applied to the second shielding portions 22. That is, the second shielding portions 22 are located in the display region 101, and constant voltages are applied to shield the influence of the charges on the display function transistors 32.

Here, when the driving function transistor 31 is turned on, the polarity of the voltage applied to the first shielding portion 21 is negative polarity, and when the driving function transistor 31 is turned off, the polarity of the voltage applied to the first shielding portion 21 is positive polarity.

Further, referring to FIG. 1 and FIG. 5, FIG. 5 is a schematic structural diagram of a scan driving circuit according to an embodiment of the present application. The setting position and the generation effect of the driving function transistors 31 in the embodiment of the present application will be described in detail with reference to the scan driving circuit.

In the embodiment of the present application, the scan driving circuit includes a plurality of scan driving units 60 arranged in cascade. Each scan driving unit 60 includes a first node control module 61, a second node control module 62, and an output module 63.

The first node control module 61 is electrically connected to a first node P and electrically connected to the second node control module 62. The first node control module 61 is configured to control a potential of the first node P. The second node control module 62 is electrically connected to a second node Q and is electrically connected to the first node control module 61. The second node control module 62 is used for controlling the potential of the second node Q. The output module 63 is electrically connected to the first node P, the second node Q, and a signal output terminal Gn of a present stage, and is configured to control the potential of the signal output terminal Gn of the present stage under the control of the potential of the first node P and the potential of the second node Q. In the present embodiment, the driving function transistors 31 are provided at least in the output module 63 to improve the stability of the signal output by the scan driving unit 60.

The first node control module 61 includes a second transistor T2, a third transistor T3, a fourth transistor T4, a fifth transistor T5, a sixth transistor T6, and a first capacitor C1. The second node control module 62 includes a seventh transistor T7, an eighth transistor T8, a ninth transistor T9, a tenth transistor T10, an eleventh transistor T11, a twelfth transistor T12, and a second capacitor C2. The output module 63 includes a first transistor T1, a thirteenth transistor T13, and a third capacitor C3. In the embodiment of the present application, the first transistor T1, the second transistor T2, the third transistor T3, the fourth transistor T4, the fifth transistor T5, the sixth transistor T6, the seventh transistor T7, the eighth transistor T8, the ninth transistor T9, the tenth transistor T10, the eleventh transistor T11, the twelfth transistor T12, and the thirteenth transistor T13 may all be P-type thin film transistors.

Specifically, the first node control module 61 is further electrically connected to a signal output terminal Gn-1 of a previous stage. In the first node control module 61, a gate of the second transistor T2 is connected to a first clock signal CK1, a source of the second transistor T2 is connected to the signal output terminal Gn-1 of the previous stage, and a drain of the second transistor T2 is connected to the node N3. And, a gate of the third transistor T3 is connected to a first constant voltage signal VGL, a source of the third transistor T3 is connected to the node N3, and a drain of the third transistor T3 is connected to the first node P. And, a gate of the fourth transistor T4 is connected to a control signal CT, a source of the fourth transistor T4 is connected to a second constant voltage signal VGH, and a drain of the fourth transistor T4 is connected to the node N3. And, a gate of the fifth transistor T5 is connected to the node N2 in the second node control module 62, a source of the fifth transistor T5 is connected to the second constant voltage signal VGH, and a drain of the fifth transistor T5 is connected to a first terminal of the first capacitor C1. And, a gate of the sixth transistor T6 is connected to the first node P, a source of the sixth transistor T6 is connected to a second clock signal CK2, and a drain of the sixth transistor T6 is connected to the first terminal of the first capacitor C1, and a second terminal of the first capacitor C1 is connected to the first node P.

In the second node control module 62, a gate of the seventh transistor T7 is connected to the first clock signal CK1, a source of the seventh transistor T7 is connected to the first constant voltage signal VGL, and a drain of the seventh transistor T7 is connected to the node N2. And, a gate of the eighth transistor T8 is connected to the first constant voltage signal VGL, a source of the eighth transistor T8 is connected to the node N2, and a drain of the eighth transistor T8 is connected to the node N1. And, a gate of the ninth transistor T9 is connected to the node N3 in the first node control module 61, a source of the ninth transistor T9 is connected to the first clock signal CK1, and a drain of the ninth transistor T9 is connected to the node N2. And, a gate of the tenth transistor T10 is connected to the node N1, a source of the tenth transistor T10 is connected to the second clock signal CK2, a drain of the tenth transistor T10 is connected to a second terminal of the second capacitor C2, and a first terminal of the second capacitor C2 is connected to the node N1. And, a gate of the eleventh transistor T11 is connected to the second clock signal CK2, a source of the eleventh transistor T11 is connected to the second terminal of the second capacitor C2, and a drain of the eleventh transistor T11 is connected to the second node Q. And, a gate of the twelfth transistor T12 is connected to the node N3 in the first node control module 61, a source of the twelfth transistor T12 is connected to the second constant voltage signal VGH, and a drain of the twelfth transistor T12 is connected to the second node Q.

In the output module 63, a gate of the first transistor T1 is connected to the first node P, a source of the first transistor T1 is connected to the first constant voltage signal VGL, and a drain of the first transistor T1 is connected to the signal output terminal Gn of the present stage. And, a gate of the thirteenth transistor T13 is connected to the second node Q, a source of the thirteenth transistor T13 is connected to the second constant voltage signal VGH and a first terminal of the third capacitor C3, and a drain of the thirteenth transistor T13 is connected to the signal output terminal Gn of the present stage. And, a second terminal of the third capacitor C3 is connected to the second node Q.

The first clock signal CK1 and the second clock signal CK2 are signals with the same periods and opposite phases. The first constant voltage signal VGL is a low potential signal, and the second constant voltage signal VGH is a high potential signal.

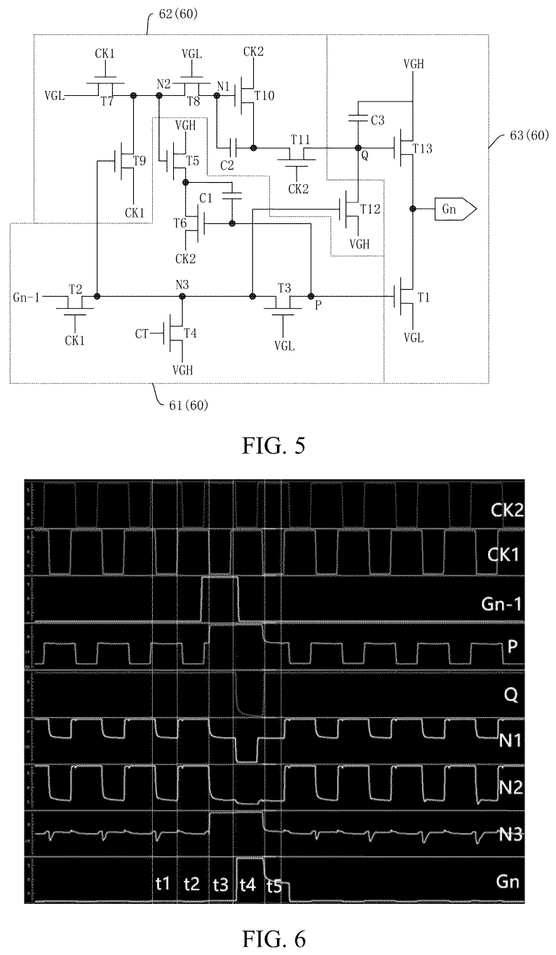

Further, referring to FIG. 5 and FIG. 6, in the time period t1, the first clock signal CK1 is low potential, the second clock signal CK2 is high potential, and the signal output terminal Gn-1 of the previous stage is low potential. At this time, the second transistor T2, the third transistor T3, the seventh transistor T7, and the eighth transistor T8 are turned on.

The low potential of the signal output terminal Gn-1 of the previous stage is output to the node N3 via the second transistor T2, and is output to the first node P via the third transistor T3. The low potential of the first constant voltage signal VGL is output to the node N2 via the seventh transistor T7, and then to the node N1 the gate of the tenth transistor T10, and the first terminal of the second capacitor C2 via the eighth transistor T8. So, the tenth transistor T10 is turned on. The high potential of the second clock signal CK2 is output to the second terminal of the second capacitor C2 via the tenth transistor T10. The gate of the fifth transistor T5 receives the low potential of the node N2 and is turned on, the high potential of the second constant voltage signal VGH is output to the first terminal of the first capacitor C1 via the fifth transistor T5, the gate of the sixth transistor T6 receives the low potential of the first node P and is turned on, the high potential of the second clock signal CK2 is output to the first terminal of the first capacitor C1, and the second terminal of the first capacitor C1 receives the low potential of the first node P. The gate of the eleventh transistor T11 receives the high potential of the second clock signal CK2 and turns off. The gate of the twelfth transistor T12 receives the low potential of the node N3 and turns on, the second constant voltage signal VGH is output to the second node Q and the second terminal of the third capacitor C3 through the twelfth transistor T12, and the first terminal of the third capacitor C3 receives the high potential of the second constant voltage signal VGH. The gate of the thirteenth transistor T13 receives the high potential of the second node Q and turns off. The gate of the first transistor T1 receives the low potential of the first node P and turns on, and the low potential of the first constant voltage signal VGL is output to the signal output terminal Gn of the present stage via the first transistor T1.

In the time period t2, the first clock signal CK1 is high potential, the second clock signal CK2 is low potential, and the signal output terminal Gn-1 of the previous stage is low potential. At this time, the second transistor T2 and the seventh transistor T7 are turned off, and the third transistor T3, the eighth transistor T8 and the eleventh transistor T11 are turned on.

The first node P receives a low potential of the second terminal of the first capacitor C1, the gate of the sixth transistor T6 receives the low potential of the second terminal of the first capacitor C1 and turns on, and the low potential of the second clock signal CK2 is output to the first terminal of the first capacitor C1 through the sixth transistor T6. And, the low potential of the first node P is output to the node N3 and the gate of the ninth transistor T9 via the third transistor T3 so that the ninth transistor T9 is turned on. The high potential of the first clock signal CK1 is transmitted to the node N2 via the ninth transistor T9, and then to the node N1 via the eighth transistor T8. The gate of the tenth transistor T10 receives the high potential of the node N1 and turns off, and the first terminal of the second capacitor C2 receives the high potential of the node N1. The gate of the twelfth transistor T12 receives the low potential of the node N3 and turns on, and the high potential of the second constant voltage signal VGH is output to the second node Q and the second terminal of the third capacitor C3 via the twelfth transistor T12. The high potential of the second node Q is output to the second terminal of the second capacitor C2 through the eleventh transistor T11. The gate of the thirteenth transistor T13 receives the high potential of the second node Q and turns off. The gate of the first transistor T1 receives the low potential of the first node P and turns on, and the first constant voltage signal VGL is output to the signal output terminal Gn of the present stage via the first transistor T1.

In the time period t3, the first clock signal CK1 is low potential, the second clock signal CK2 is high potential, and the signal output terminal Gn-1 of the previous stage is high potential. At this time, the second transistor T2, the third transistor T3, the seventh transistor T7, and the eighth transistor T8 are turned on, and the eleventh transistor T11 is turned off.

The high potential of the signal output terminal Gn-1 of the previous stage is output to the node N3 via the second transistor T2, and is output to the first node P via the third transistor T3, and the gate of the first transistor Tl receives the high potential of the first node P and turns off. The gate of the sixth transistor T6 receives the high potential of the first node P and turns off, the second terminal of the first capacitor C1 receives the high potential of the first node P, and the gate of the ninth transistor T9 receives the high potential of the node N3 and turns off. The low potential of the first constant voltage signal VGL is output to the node N2 via the seventh transistor T7 and is output to the node N1 via the eighth transistor T8, the gate of the tenth transistor T10 receives the low potential of the node N1 and turns on, the high potential of the second clock signal CK2 is output to the second terminal of the second capacitor C2 via the tenth transistor T10, and the first terminal of the second capacitor C2 receives the low potential of the node N1. The gate of the fifth transistor T5 receives the low potential of the node N2 and turns on, and the high potential of the second constant voltage signal VGH is output to the first terminal of the first capacitor C1 via the fifth transistor T5. The gate of the twelfth transistor T12 receives the high potential of the node N3 and turns off. The second node Q receives the high potential of the second terminal of the third capacitor C3 and turns off.

In the time period t4, the first clock signal CK1 is high potential, the second clock signal CK2 is low potential, and the signal output terminal Gn-1 of the previous stage is low potential. At this time, the second transistor T2 and the seventh transistor T7 are turned off, and the third transistor T3, the eighth transistor T8 and the eleventh transistor T11 are turned on.

The first node P receives a high potential of the second terminal of the first capacitor C1 and outputs the high potential to the node N3 through the third transistor T3. The gate of the first transistor T1 receives the high potential of the first node P and turns off, the gate of the ninth transistor T9 receives the high potential of the node N3 and turns off, and the sixth transistor T6 receives the high potential of the first node P and turns off. The node N1 receives the low potential of the first terminal of the second capacitor C2 and turns on, the low potential of the second clock signal CK2 is output to the second terminal of the second capacitor C2 via the tenth transistor T10 and transmitted to the second node Q via the eleventh transistor T11, the second terminal of the third capacitor C3 receives the low potential of the second node Q, the gate of the thirteenth transistor T13 receives the low potential of the second node Q and turns on, and the high potential of the second constant voltage signal VGH is output to the signal output terminal Gn of the present stage via the thirteenth transistor T13.

In the time period t5, the first clock signal CK1 is low potential, the second clock signal CK2 is high potential, and the signal output terminal Gn-1 of the previous stage is low potential. At this time, the second transistor T2, the third transistor T3, the seventh transistor T7, and the eighth transistor T8 are turned on, and the eleventh transistor T11 is turned off.

The low potential of the signal output terminal Gn-1 of the previous stage is output to the node N3 through the second transistor T2, and is output to the first node P through the third transistor T3, the gate of the sixth transistor T6 receives the low potential of the first node P and turns on, the high potential of the second clock signal CK2 is output to the first terminal of the first capacitor C1, and the second terminal of the first capacitor C1 receives the low potential of the first node P. The gate of the ninth transistor T9 receives a low potential of the node N3 and turns on, the low potential of the first clock signal CK1 is output to the node N2 via the ninth transistor T9, the gate of the fifth transistor T5 receives a low potential of the node N2 and turns on, and the high potential of the second constant voltage signal VGH is output to the first terminal of the first capacitor C1 via the fifth transistor T5. The low potential of the node N2 is transmitted through the eighth transistor T8 to the node N1, the first terminal of the second capacitor C2, and the gate of the tenth transistor T10. The tenth transistor T10 turns on and outputs the high potential of the second clock signal CK2 to the second terminal of the second capacitor C2. The gate of the twelfth transistor T12 receives the low potential of the node N3 and turns on, the high potential of the second constant voltage signal VGH is output to the second node Q and the second terminal of the third capacitor C3 via the twelfth transistor T12, the gate of the thirteenth transistor T13 receives the high potential of the second node Q and turns off, the gate of the first transistor T1 receives the low potential of the first node P and turns on, and the low potential of the first constant voltage signal VGL is output to the signal output terminal Gn of the present stage via the first transistor T1. Here, since the first node P is connected to the second terminal of the first capacitor C1, the first node P changes from the high potential at the time period t4 to the low potential at the time period t5. Because the charging speed of the capacitor is relatively slow, the potential of the first node P cannot completely turn on the first transistor T1, a delay phenomenon occurs when the signal output terminal Gn of the present stage changes from the high potential at the time period t4 to the low potential at the time period t5.

Then, the first node control module 61 controls the potential of the first node P, and the second node control module 62 controls the potential of the second node Q. The output module 63 outputs a signal to the signal output terminal Gn of the present stage according to the potential of the first node P and the potential of the second node Q, so as to output a scan signal to each pixel driving unit in the display area 101, and to control the turn-on and the turn-off of the transistors in the pixel driving unit, thereby realizing the light emission of each pixel in the display area 101.

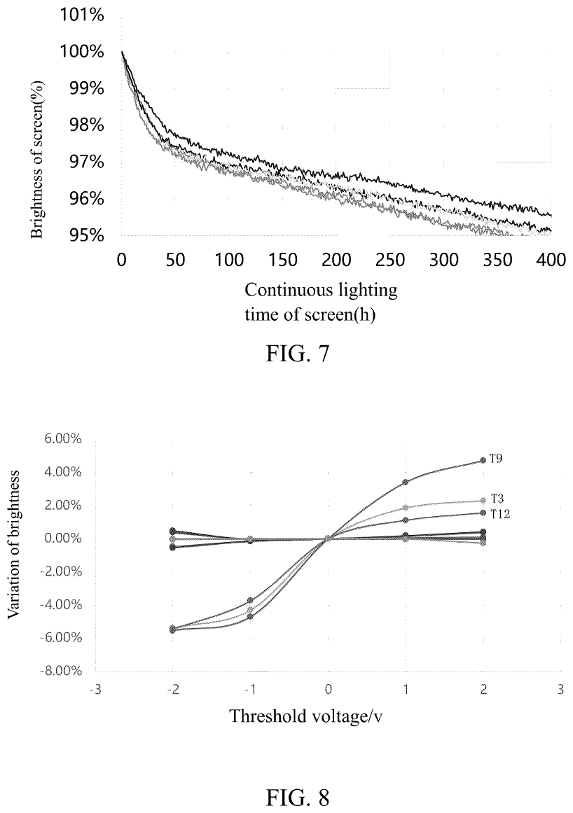

The embodiment of the present application verifies the relationship between the lighting time and the brightness of the display panel to obtain a structure as shown in FIG. 7. It can be seen from FIG. 7 that, the brightness of the display panel gradually decreases along with the increase of the lighting time of the display panel. From the screen analysis, it can be seen that the drift of the threshold voltage occurs due to the poor reliability of the transistors in the scan driving unit 60, which causes the signal output by the scan driving unit 60 to fluctuate, thereby reducing the brightness of the display panel.

Further, the embodiment of the present application verifies the transistors in the scan driving unit 60 of the display panel to obtain the results shown in FIGS. 8, 9, 10, and 11.

FIG. 8 shows a simulation analysis of each transistor in the scan driving unit 60, and the verification for the degree of influence of the drift of the threshold voltage of each transistor on the brightness of the display panel. It can be seen from FIG. 8 that when the threshold voltages of the first transistor T1, the second transistor T2, and the third transistor T3 drift, the brightness of the display panel changes greatly. Therefore, it can be seen that the reliability of the first transistor T1, the second transistor T2, and the third transistor T3 is the main factor influencing the stability of the signal output by the scan driving unit 60.

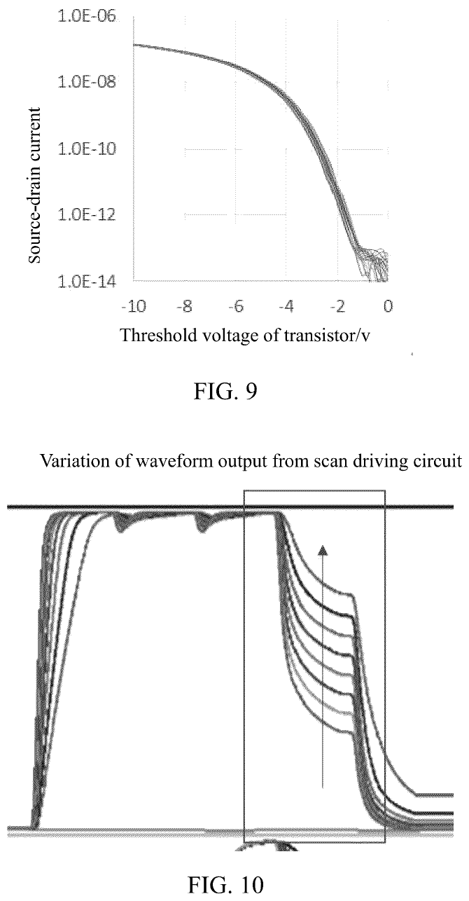

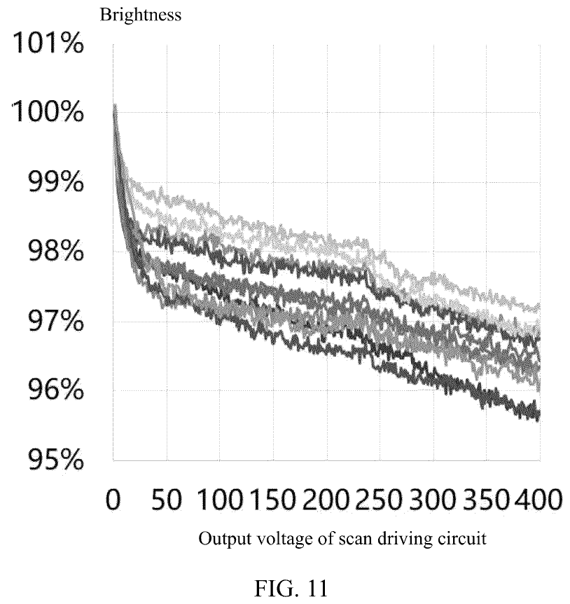

Specifically, as shown in FIG. 9, the threshold voltages of the first transistor T1, the second transistor T2, and the third transistor T3 gradually shift negatively along with the increase of the driving time. As shown in FIG. 10, the abscissa represents the threshold voltage of the transistor, and the ordinate represents the output voltage of the scan driving unit 60, that is, the potential of the signal output terminal Gn of the present stage. The output voltage of the scan driving unit 60 gradually rises along with the threshold voltages of the first transistor T1, the second transistor T2, and the third transistor T3 are negatively shifted. As shown in FIG. 11, as the output voltage of the scan driving unit 60 rises, the brightness of the display panel gradually decreases.

It can be seen that the stability of the first transistor T1 has the greatest effect on the signal output stability of the scan driving unit 60, the stability of the second transistor T2 has the second effect on the signal output stability of the scan driving unit 60, and the stability of the third transistor T3 has only the smaller effect on the signal output stability of the scan driving unit 60 than the first transistor T1 and the second transistor T2.

Therefore, in the present embodiment, the driving function transistor 31 at least includes the first transistor T1. That is, the first shielding portion 21 is provided between the first transistor T1 and the substrate 10 to improve the reliability of the first transistor T1 and the signal output stability of the scan driving unit 60, and to improve the display brightness and the display effect of the display panel.

Further, the driving function transistor 31 may further include a second transistor T2 and a third transistor T3. That is, the first shielding portion 21 is provided between the second transistor T2 and the substrate 10, and between the third transistor T3 and the substrate 10, so as to further improve the reliability of the first transistor T1 and the signal output stability of the scan driving unit 60, and improve the display brightness and the display effect of the display panel.

It will be appreciated that the driving function transistor 31 may also include other transistors in the scan driving unit 60, which is not limited herein. The first transistor T1, the second transistor T2, and the third transistor T3 have the greatest influence on the signal output stability of the scan driving unit 60. Therefore, it is preferable to improve the stability of the first transistor T1, the second transistor T2, and the third transistor T3.

According to the embodiment of the present application, the first shielding portion 21 is provided between the driving function transistor 31 located in the scan driving circuit sub-area 1021 and the substrate 10, and the first shielding portion 21 has an electric field shielding effect, so that the charges generated by voltage induction in the substrate 10 do not affect the threshold voltage of the driving function transistor 31, thereby improving the stability of the driving function transistor 31, improving the stability of the output voltage of the scan driving circuit sub-area 1021, and improving the brightness stability and the display effect of the display panel. In addition, in the embodiment of the present application, a variable voltage is applied to the first shielding portion 21. Since the first shielding portion 21 is located below the driving function transistor 31, the polarity of the voltage applied to the first shielding portion 21 can be adjusted to increase the driving current of the driving function transistor 31, thereby further improving the signal transmission efficiency and the display effect of the display panel.

Embodiments of the present application further provide a display panel. Referring to FIG. 2, in the present embodiment, the first shielding portion 21 and the second shielding portion 22 are located on the same layer, and the first shielding portion 21 and the second shielding portion 22 are connected to each other and are loaded with the same potentials. Further, the number of the driving function transistors 31 is multiple and the number of the display function transistors 32 is multiple. The number of the first shielding portions 21 and the number of the second shielding portions 22 are each multiple. The multiple first shielding portions 21 and the multiple second shielding portions 22 are connected to form a mesh structure. Further, the first shielding portions 21 and the second shielding portions 22 may be formed in the same photomask, and it is not necessary to provide additional wiring for the second shielding portion 22 for loading voltage, thereby saving a process procedure, reducing a process cost, and simplifying a structure of the display panel.

Further, the display panel further includes a plurality of pixel driving units provided in the display area 101 to receive a scanning signal output from each of the scan driving units 60 and to drive pixels in each of the pixel driving units to emit light. In the embodiment of the present application, the display function transistor 32 is provided in the pixel driving unit. Since each scan driving unit 60 needs to drive the transistors in the plurality of pixel driving units, the sizes of the transistors in the scan driving unit 60 are larger than the sizes of the transistors in the pixel driving unit. That is, the sizes of the driving function transistors 31 are larger than the sizes of the display function transistors 32. Therefore, the area of the orthographic projection of the first shielding portion 21 on the substrate 10 is larger than the orthographic projection area of the second shielding portion 22 on the substrate 10. And, the area of the orthographic projection of the first shielding portion 21, which is corresponding to one scan driving unit 60, on the substrate 10 is larger than the orthographic projection area of the second shielding portion 22, which is corresponding to one pixel driving unit 60, on the substrate 10.

It will be appreciated that the first shielding portion 21 and the second shielding portion 22 are provided in the same layer, and may be located on the substrate 10 and covered by the passivation layer 11, as shown in FIG. 2; and may be on the passivation layer 11 and covered by the buffer layer 33, as shown in FIG. 1, which is not limited herein.

The circuit structure and the driving timing of the scan driving units 60 in the display panel according to the present embodiment may be set with reference to the previous embodiments, which is not described here. The driving function transistor 31 may also include the first transistor T1, the second transistor T2, and the third transistor T3, or may include other transistors in the scan driving unit 60.

According to the embodiment of the present application, the first shielding portion 21 is provided between the driving function transistor 31 located in the scan driving circuit sub-area 1021 and the substrate 10, and the first shielding portion 21 has an electric field shielding effect, so that the charges generated by voltage induction in the substrate 10 do not affect the threshold voltage of the driving function transistor 31, thereby improving the stability of the driving function transistor 31, improving the stability of the voltage output by the scan driving circuit sub-area 1021, and improving the brightness stability and the display effect of the display panel. In addition, according to the embodiment of the present application, the first shielding portion 21 and the second shielding portion 22 are provided in the same layer and connected, and the first shielding portion 21 and the second shielding portion 22 are loaded with the same voltage, so that the first shielding portion 21 and the second shielding portion 22 can be formed in the same photomask, and it is not necessary to load the additional wiring for the second shielding portion 22 for loading the voltage, thereby saving the process procedure, reducing the process cost, and simplifying the structure of the display panel.

In addition, an embodiment of the present application further provides a display device including the display panel described in the above embodiments and a device body.

In the embodiment of the present application, the device body may include a middle frame, a driving assembly, a power supply, and the like. The display device may be a display terminal such as a mobile phone, a tablet, or a television, which is not limited herein.

In the above-mentioned embodiments, the description of each embodiment has its own emphasis, and parts not described in detail in a certain embodiment may be referred to the related description of other embodiments.

The display panel and the display device provided by embodiments of the present application have been described in detail. The principles and the embodiments of the present application have been described with reference to specific examples. The description of the above embodiments is merely provided to help understand the technical solution and the core idea of the present application. It will be appreciated by those of ordinary skill in the art that modifications may still be made to the technical solutions described in the foregoing embodiments, or equivalents may be made to some of the technical features therein. These modifications or these substitutions do not depart the essence of the corresponding technical solutions from the scope of the technical solutions of the embodiments of the present application.

1. A display panel comprising a display area, a non-display area adjacent to the display area, and the non-display area comprising a scan driving circuit sub-area;
the display panel further comprising:
a substrate;
a shielding layer disposed on the substrate; and
a driving circuit layer disposed on a side of the shielding layer which is away from the substrate, wherein the driving circuit layer comprises a driving function transistor disposed in the scan driving circuit sub-area;
wherein the shielding layer comprises a first shielding portion between the driving function transistor and the substrate, and the first shielding portion is configured to be supplied with a voltage that is variable.

2. The display panel according to claim 1, wherein the driving circuit layer further comprises a display function transistor disposed in the display area, and the shielding layer further comprises a second shielding portion disposed between the display function transistor and the substrate;
wherein when both the driving function transistor and the display function transistor are turned on, a polarity of the voltage of the first shielding portion is opposite to a polarity of a voltage of the second shielding portion, and when both the driving function transistor and the display function transistor are turned off, the polarity of the voltage of the first shielding portion is the same as the polarity of the voltage of the second shielding portion.

3. The display panel according to claim 1, wherein a polarity of the voltage of the first shielding portion is a negative polarity when the driving function transistor is turned on, and a polarity of the voltage of the first shielding portion is a positive polarity when the driving function transistor is turned off.

4. The display panel according to claim 1, wherein the driving function transistor comprises an active layer, a gate, a source, and a drain, wherein the active layer is provided on a side of the first shielding portion which is away from the substrate, the gate is provided on a side of the active layer which is away from the first shielding portion, the source and the drain are provided on a side of the gate which is away from the active layer, and the source and the drain overlap with two sides of the active layer;
wherein the first shielding portion is electrically connected to the gate.

5. The display panel according to claim 1, wherein the display panel further comprises a scan driving circuit disposed in the scan driving circuit sub-area, the scan driving circuit comprises a plurality of scan driving units cascaded, and each of the plurality of scan driving units comprises a first node control module, a second node control module, and an output module;
the first node control module is electrically connected to a first node and electrically connected to the second node control module, and the first node control module is configured to control a potential of the first node;
the second node control module is electrically connected to a second node and electrically connected to the first node control module, and the second node control module is configured to control a potential of the second node;
the output module is electrically connected to the first node, the second node, and a signal output terminal of a present stage, and the output module is configured to control a potential of the signal output terminal of the present stage under a control of the potential of the first node and the potential of the second node;
wherein the driving function transistor is disposed at least in the output module.

6. The display panel according to claim 5, wherein the output module comprises a first transistor connected between the signal output terminal of the present stage and the first node, and the driving function transistor comprises the first transistor.

7. The display panel according to claim 6, wherein the first node control module is electrically connected to a signal output terminal of a previous stage, the first node control module further comprises a second transistor and a third transistor connected between the signal output terminal of the previous stage and the first transistor, and the driving function transistor further comprises a second transistor and/or a third transistor.

8. A display panel comprising a display area, a non-display area adjacent to the display area, and the non-display area comprising a scan driving circuit sub-area;
the display panel further comprising:
a substrate;
a shielding layer disposed on the substrate; and
a driving circuit layer disposed on a side of the shielding layer which is away from the substrate, wherein the driving circuit layer comprises one or more driving function transistors disposed in the scan driving circuit sub-area and one or more display function transistors disposed in the display region;
wherein the shielding layer comprises one or more first shielding portions each of which is between a corresponding one of the one or more driving function transistors and the substrate, and one or more second shielding portions each of which is disposed between a corresponding one of the one or more display function transistors and the substrate, and the first shielding portion is connected to the second shielding portion.

9. The display panel according to claim 8, wherein the one or more driving function transistors comprise a plurality of driving function transistors, and the one or more display function transistors comprise a plurality of display function transistors; the one or more first shielding portions comprise a plurality of first shielding portions each of which is between a corresponding one of the driving function transistors and the substrate, and the one or more second shielding portions comprise a plurality of second shielding portions each of which is between a corresponding one of the display function transistors and the substrate;
wherein the plurality of first shielding portions and the plurality of second shielding portions are connected to form a network structure.

10. The display panel according to claim 9, wherein the display panel further comprises a scan driving circuit disposed in the scan driving circuit sub-area, the scan driving circuit comprises a plurality of scan driving units cascaded, and each of the plurality of scan driving units comprises a first node control module, a second node control module, and an output module;
the first node control module is electrically connected to a first node and electrically connected to the second node control module, and the first node control module is configured to control a potential of the first node;
the second node control module is electrically connected to a second node, and electrically connected to the first node control module, and the second node control module is configured to control a potential of the second node;
the output module is electrically connected to the first node, the second node, and a signal output terminal of a present stage, and the output module is configured to control a potential of the signal output terminal of the present stage under a control of the potential of the first node and the potential of the second node;
wherein the one or more driving function transistors are disposed at least in the output module.

11. The display panel according to claim 10, wherein the output module comprises a first transistor connected between the signal output terminal of the present stage and the first node, and the driving function transistor comprises the first transistor.

12. The display panel according to claim 11, wherein the first node control module is electrically connected to a signal output terminal of a previous stage, the first node control module further comprises a second transistor and a third transistor connected between the signal output terminal of the previous stage and the first transistor, and the driving function transistor further comprises the second transistor and/or the third transistor.

13. The display panel according to claim 10, wherein the display panel further comprises a plurality of pixel driving units provided in the display area, the one or more display function transistors are provided in the pixel driving units;
wherein an area of an orthographic projection of the first shielding portion, which is corresponding to a respective one of the plurality of scan driving units, on the substrate is larger than an area of an orthographic projection of the second shielding portion, which is corresponding to a respective one of the pixel driving units, on the substrate.

14. A display device comprising a display panel comprising a display area, a non-display area adjacent to the display area, the non-display area comprising a scan driving circuit sub-area;
the display panel further comprising:
a substrate;
a shielding layer disposed on the substrate; and
a driving circuit layer disposed on a side of the shielding layer which is away from the substrate, wherein the driving circuit layer comprises a driving function transistor disposed in the scan driving circuit sub-area;
wherein the shielding layer comprises a first shielding portion between the driving function transistor and the substrate, and the first shielding portion is configured to be supplied with a voltage that is variable.

15. The display device according to claim 14, wherein the driving circuit layer further comprises a display function transistor disposed in the display area, and the shielding layer further comprises a second shielding portion disposed between the display function transistor and the substrate;
wherein when both the driving function transistor and the display function transistor are turned on, a polarity of the voltage of the first shielding portion is opposite to a polarity of a voltage of the second shielding portion, and when both the driving function transistor and the display function transistor are turned off, the polarity of the voltage of the first shielding portion is the same as the polarity of the voltage of the second shielding portion.

16. The display device according to claim 14, wherein a polarity of the voltage of the first shielding portion is a negative polarity when the driving function transistor is turned on, and a polarity of a voltage of the first shielding portion is a positive polarity when the driving function transistor is turned off.

17. The display device according to claim 14, wherein the driving function transistor comprises an active layer, a gate, a source, and a drain, wherein the active layer is provided on a side of the first shielding portion which is away from the substrate, the gate is provided on a side of the active layer which is away from the first shielding portion, the source and the drain are provided on a side of the gate which is away from the active layer, and the source and the drain overlap with two sides of the active layer;
wherein the first shielding portion is electrically connected to the gate.

18. The display device according to claim 14, wherein the display panel further comprises a scan driving circuit disposed in the scan driving circuit sub-area, the scan driving circuit comprises a plurality of scan driving units cascaded, and each of the scan driving units comprises a first node control module, a second node control module, and an output module;
the first node control module is electrically connected to a first node and electrically connected to the second node control module, and the first node control module is configured to control a potential of the first node;
the second node control module is electrically connected to a second node and electrically connected to the first node control module, and the second node control module is configured to control a potential of the second node;
the output module is electrically connected to the first node, the second node, and a signal output terminal of a present stage, and the output module is configured to control a potential of the signal output terminal of the present stage under a control of the potential of the first node and the potential of the second node;
wherein the driving function transistor is disposed at least in the output module.

19. The display device according to claim 18, wherein the output module comprises a first transistor connected between the signal output terminal of the present stage and the first node, and the driving function transistor comprises the first transistor.

20. The display device according to claim 19, wherein the first node control module is electrically connected to a signal output terminal of a previous stage, the first node control module further comprises a second transistor and a third transistor connected between the signal output terminal of the previous stage and the first transistor, and the driving function transistor further comprises the second transistor and/or the third transistor.
